(19) United States
(12) Patent Application Publication
(10) Pub. No.: US 2026/0107422 A1
(43) Pub. Date: Apr. 16, 2026

(54) UNIVERSAL SPACERS FOR MODULAR HYBRID-COOLED HIGH-DENSITY DATA CENTER PODS

(71) Applicant: Deep Cool AI, Inc., Fremont, CA (US)

(72) Inventors: Tikhon Suresh Pichai, Fremont, CA (US); Davood Ghadiri Moghaddam, Richmond Hill (CA); Kris Holla, Fremont, CA (US)

(73) Assignee: Deep Cool AI, Inc., Fremont, CA (US)

(21) Appl. No.: 19/352,371

(22) Filed: Oct. 7, 2025

Related U.S. Application Data
(60) Provisional application No. 63/704,779, filed on Oct. 8, 2024.

(51) Int. Cl. H05K 7/20; G05B 13/04

(52) U.S. Cl. CPC H05K 7/20836; G05B 13/048; H05K 7/20736; H05K 7/20781

(57) ABSTRACT

A modular hybrid-cooled data center rack adapter system integrates a transverse spacer adapter, longitudinal flow spacer, rear-door heat exchanger, coolant distribution unit, and controls and sensor suite to enable universal mechanical and fluidic adaptation of multi-vendor heat exchangers to diverse rack geometries. The rack distribution manifold and redundant rack power distribution units are incorporated within the spacer assembly, providing integrated liquid and power distribution. The longitudinal flow spacer, positive return-flow fan array, and gravity backflow dampers manage airflow to prevent hot-aisle dilution. The hybrid air-liquid rack cooling control method utilizes sensor telemetry, dewpoint sensing, and a model-predictive control variant to dynamically coordinate air-side and liquid-side cooling resources, maintain condensation safety, and optimize the air-to-liquid heat removal ratio. The invention enables scalable transition between air-dominant and liquid-dominant cooling modes without extensive cabinet modification, addressing condensation risk and operational efficiency in heterogeneous data center environments.

### CROSS REFERENCE TO RELATED APPLICATIONS

This application claims priority to U.S. Provisional Application No. 63/704,799, filed Oct. 8, 2024, the entirety of which is incorporated by reference.

### BACKGROUND

Thermal management of data center racks has become increasingly complex due to the proliferation of high-density computing equipment and the adoption of diverse cooling technologies. One persistent challenge in this field is the lack of a universal adapter capable of mechanically mating rear-door heat exchangers (RDHX) from multiple vendors to a wide variety of rack geometries. Existing solutions are often vendor-specific, requiring custom brackets or adapters for each combination of RDHX and rack type. This approach leads to increased installation complexity, higher costs, and limited flexibility when integrating new or replacement cooling hardware into heterogeneous data center environments.

Another significant problem in data center rack cooling is the absence of integrated assemblies that combine rack-level liquid distribution manifolds with redundant power distribution units. Conventional designs typically treat liquid cooling distribution and power delivery as separate subsystems, resulting in increased spatial requirements, more complex cabling and piping layouts, and greater difficulty in managing and maintaining these critical infrastructure elements. The lack of integration can also hinder rapid deployment and complicate the implementation of redundancy strategies at the rack level.

Uncontrolled or reverse airflow between adjacent racks presents further challenges to efficient data center cooling. In many installations, gaps between racks or poorly sealed rack-to-rack interfaces allow air to bypass intended flow paths, leading to hot-aisle dilution and reduced cooling effectiveness. Such airflow anomalies can cause elevated inlet temperatures for IT equipment, increase the risk of thermal hotspots, and reduce the overall efficiency of both air-side and liquid-side cooling systems.

Maintaining an optimal balance between air-side and liquid-side heat removal is also problematic in current data center cooling architectures. Existing systems often lack the capability to dynamically coordinate and sustain a target ratio of heat removal via air and liquid under varying computational loads. This limitation can result in suboptimal energy usage, insufficient cooling during peak loads, or unnecessary overprovisioning of cooling resources, all of which negatively impact operational efficiency and cost.

The risk of condensation forming on RDHX coils due to insufficient dewpoint margin management in secondary water loops is another area of concern. Traditional cooling systems may not provide adequate monitoring or control of water temperatures relative to ambient dewpoint, increasing the likelihood of condensation. Such condensation can lead to water accumulation, equipment corrosion, and potential electrical hazards within the data center environment.

Finally, scaling from air-dominant to liquid-dominant cooling approaches remains difficult without extensive modification or replacement of existing rack cabinets. Many legacy systems are not designed to accommodate liquid cooling infrastructure, and retrofitting these systems often requires significant downtime, capital expenditure, and operational disruption. The lack of scalable, modular solutions impedes the adoption of advanced cooling technologies and limits the ability of data center operators to respond to evolving thermal management requirements.

### SUMMARY

The modular hybrid-cooled data center rack adapter system and the associated hybrid air-liquid rack cooling control method provide an integrated solution for flexible, efficient, and safe thermal management in data center environments. The modular hybrid-cooled data center rack adapter system comprises a transverse spacer adapter (TSA), a longitudinal flow spacer (LFS), a rack distribution manifold (RDM), a rear-door heat exchanger (RDHX), a coolant distribution unit (CDU), and a controls and sensor suite. The hybrid air-liquid rack cooling control method utilizes a model-predictive control (MPC) variant to dynamically coordinate air-side and liquid-side cooling resources, maintain condensation safety, and handle fault conditions. The invention enables seamless adaptation to a wide range of rack geometries and cooling requirements, supporting both air-dominant and liquid-dominant operation without extensive cabinet modifications.

The modular hybrid-cooled data center rack adapter system addresses the lack of a universal adapter for mechanically mating multi-vendor rear-door heat exchangers to various rack geometries by incorporating the transverse spacer adapter (TSA) with reversible mating flanges and a depth shim set. The TSA's adjustable and modular design enables mechanical compatibility with a range of rack depths and mounting patterns, providing a universal interface for rear-door heat exchangers from multiple vendors. This approach improves upon prior art by eliminating the need for custom fabrication or vendor-specific adapters, thereby reducing installation complexity and deployment time.

The invention solves the absence of integrated rack-level liquid distribution manifolds and redundant power distribution units within a single spacer assembly by integrating the rack distribution manifold (RDM) and redundant rack power distribution units (RPDUs) into the TSA. The RDM includes inlet and outlet headers, isolation valves, dry-break couplings, and flow/Δp instrumentation, while the RPDUs provide electrical redundancy and includebonding/grounding studsand cable glands. This integration consolidates liquid and power distribution within a single modular assembly, reducing the rack footprint and simplifying serviceability compared to separate, externally mounted components.

The longitudinal flow spacer (LFS), equipped with gravity backflow dampers and a positive return-flow fan (PRFF) array, addresses uncontrolled or reverse airflow between adjacent racks, which leads to hot-aisle dilution and cooling inefficiency. The LFS's active airflow management, including modulating fan speed to maintain differential pressure, ensures unidirectional airflow and prevents recirculation. This configuration provides a measurable improvement in cooling efficiency and thermal isolation between racks relative to passive or non-integrated airflow management solutions.

The hybrid air-liquid rack cooling control method, executed by the controller within the controls and sensor suite, overcomes the inability to dynamically coordinate and maintain a target ratio of air-side and liquid-side heat removal under varying loads. The method collects air-side and water-side measurements, computes a dewpoint margin, and determines a desired air-to-liquid heat removal ratio. The method then coordinates the adjustment of liquid flow, RDHX water flow, and LFS fan speed to achieve the calculated cooling targets. The use of a model-predictive control (MPC) variant enables anticipatory and adaptive control, resulting in improved thermal stability and energy efficiency compared to static or rule-based control schemes.

The risk of condensation on RDHX coils due to insufficient dewpoint margin management in secondary water loops is mitigated by the invention's condensation safety protocol. The controls and sensor suite, including a dewpoint sensor and differential-pressure sensors, continuously monitor the rack ambient dewpoint and RDHX supply temperature. The method compares the RDHX supply temperature to the computed dewpoint margin and, if necessary, reduces RDHX duty or increases water temperature to maintain a safe margin. This active management prevents condensation events and associated equipment damage, representing a significant advancement over prior systems lacking integrated dewpoint monitoring and response.

The invention facilitates scaling from air-dominant to liquid-dominant cooling without replacing or extensively modifying existing cabinets by providing a modular architecture. The modular hybrid-cooled data center rack adapter system's components, including the TSA, LFS, and RDM, are designed for retrofit installation and compatibility with a range of rack and cooling configurations. The hybrid air-liquid rack cooling control method supports seamless transitions between cooling modes by dynamically adjusting the proportion of air-side and liquid-side heat removal. This capability enables data center operators to incrementally adopt liquid cooling as thermal loads increase, preserving capital investment in existing infrastructure and minimizing operational disruption.

### BRIEF DESCRIPTION OF FIGURES

FIG. 1 is a schematic representation of one variant of the Transverse Spacer Adapter (TSA) and related components.

FIG. 2 is a schematic representation of one variant of the longitudinal flow spacer (LFS) as integrated with surrounding components.

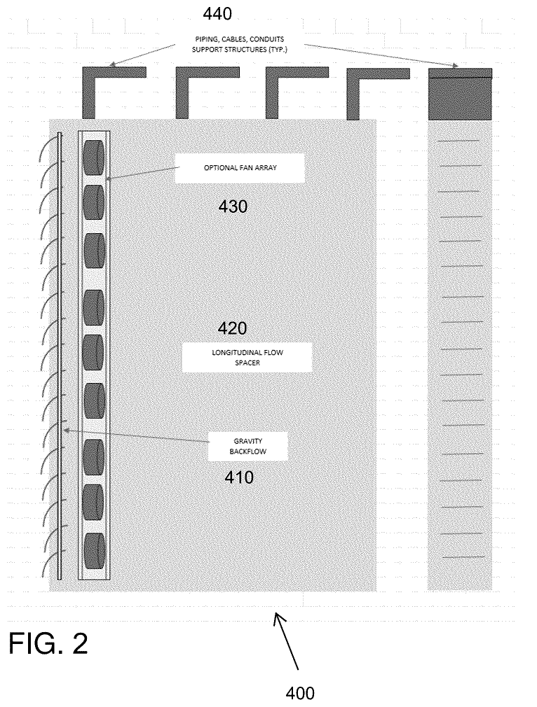

FIG. 3 is an expanded view of FIG. 1 illustrating the LFS in greater detail.

FIG. 4 is a schematic representation of one variant of the longitudinal flow spacer (LFS) or transverse spacer in greater detail.

### REFERENCE NUMBERS

110 rack distribution manifold
120 rack distribution manifold front view
125 rack distribution manifold side view
200 transverse spacer
210 adjustable sliding mating flange to mate with smaller or larger cabinet dimensions
220 mounting frame
230 adjustable sliding mating flange on all sides to mate with smaller or larger RDHX dimensions
300 Rack PDU
400 server
410 gravity backflow
420 longitudinal flow spacer
430 optional fan array
440 piping cables, conduits, support structures

### DETAILED DESCRIPTION

### Modular Hybrid-Cooled Data Center Rack Adapter System

The modular hybrid-cooled data center rack adapter system can retrofit information-technology racks for hybrid air- and liquid-cooled operation by providing a transverse spacer adapter (TSA) that mounts between a rack and a rear-door heat exchanger and by providing a longitudinal flow spacer (LFS) that guides return airflow between adjacent racks. The modular hybrid-cooled data center rack adapter system can include reversible mating flanges, elongated slots, and a depth shim set to establish multi-vendor mechanical interfaces while preserving alignment across varying rack depths. The modular hybrid-cooled data center rack adapter system can house an integrated rack distribution manifold with isolation valves, dry-break couplings, and flow/Δp instrumentation and can mount redundant rack power distribution units within an adapter cavity to conserve U-space and reduce cable congestion. The modular hybrid-cooled data center rack adapter system can position gravity backflow dampers and a variable-speed positive return-flow fan array within the LFS to maintain a positive differential pressure from rack exhaust to rack intake and to limit uncontrolled or reverse airflow. The modular hybrid-cooled data center rack adapter system can distribute a controls and sensor suite across the TSA and the LFS to monitor temperatures, pressures, flow rates, dewpoint, and condensate and can employ a controller to coordinate LFS fan speed, rear-door heat exchanger water flow, and coolant distribution unit liquid conditions to achieve a commanded air-to-liquid heat removal ratio while maintaining a dewpoint margin. The modular hybrid-cooled data center rack adapter system can support incremental migration from air-dominant to liquid-dominant cooling by enabling the addition of liquid capacity without cabinet replacement and can provide hot-swappable fan trays and service panels to streamline maintenance. The modular hybrid-cooled data center rack adapter system can incorporate a condensate management assembly, electromagnetic-interference gasketing with bonding points, and physical separation of power and liquid conduits to satisfy safety and compliance objectives. The modular hybrid-cooled data center rack adapter system can scale to pod-level deployments by coordinating multiple rack-spacer assemblies for room-neutral thermal performance within a defined operating envelope. The modular hybrid-cooled data center rack adapter system therefore addresses the lack of a universal rack-to-rear-door interface, the absence of integrated liquid and power distribution, the prevalence of reverse or uncontrolled inter-rack airflow, the need for dynamic air-to-liquid coordination with condensation safety, and the difficulty of scaling cooling capacity without extensive cabinet modification.

### Transverse Spacer Adapter (TSA)

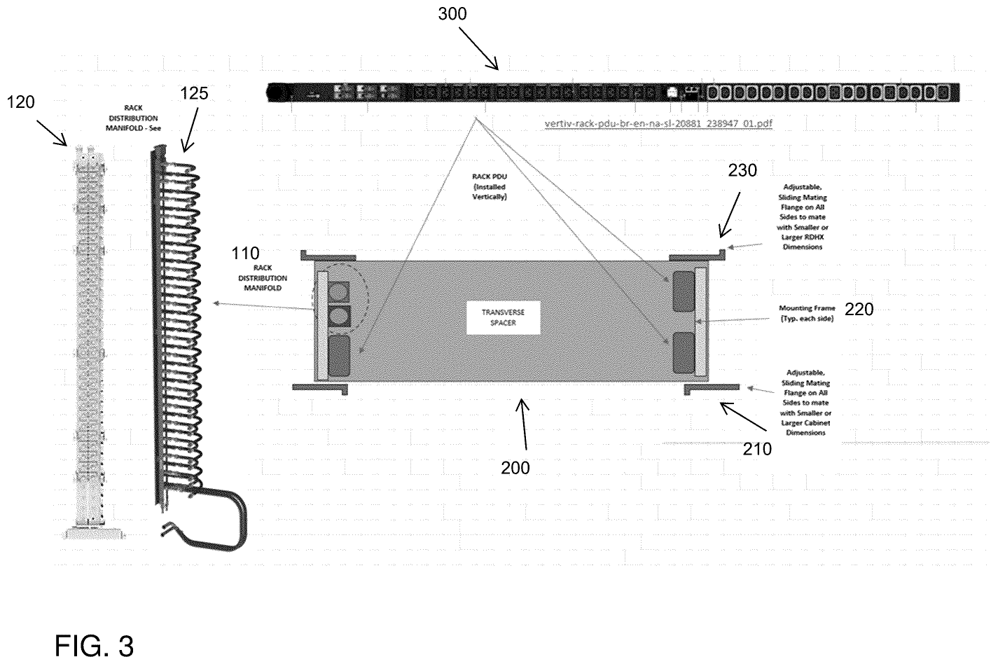

As shown in FIG. 3, the transverse spacer adapter (TSA) can provide a modular structural interface between an information-technology equipment rack and a rear-door heat exchanger by creating a depth-adjustable standoff that aligns hinge axes and maintains seal compression under door masses in an exemplary range of 50-150 kg. Generally, the transverse spacer adapter (TSA) can include mirrored reversible bolt-pattern mating flanges with elongated slots and a stackable depth shim set to accommodate multiple rack widths (e.g., 600-800 mm) and various rear-door heat exchanger hinge and latch geometries without modification to the rack and/or the rear-door heat exchanger. More specifically, the transverse spacer adapter (TSA) can define an adapter cavity that locates a rack distribution manifold and redundant rack power distribution units on opposed rails to free vertical rack U-space and to reduce cable congestion while maintaining separation between electrical and liquid conduits. In one embodiment, the transverse spacer adapter (TSA) can integrate cable glands and a drip-tray path to provide strain relief and to route condensate away from electrical interfaces, and the transverse spacer adapter (TSA) can incorporate electromagnetic-interference gasketing and bonding points to establish a low-impedance ground path and to maintain enclosure shielding continuity. Additionally, the transverse spacer adapter (TSA) can incorporate condensate management features, such as sloped trays, drains, and leak sensors, and the transverse spacer adapter (TSA) can position temperature and dewpoint sensor to enable control of rear-door heat exchanger supply-water temperature above room dewpoint by an exemplary margin of at least 2-5° C. In one implementation, the transverse spacer adapter (TSA) can provide tool-less or quarter-turn fastener access to service panels and can allow field reversibility of door hinge orientation to support rapid retrofit across multi-vendor rack fleets. Alternatively, the transverse spacer adapter (TSA) can offer mounting locations for auxiliary modules, such as switchgear and/or pump modules, provided that the transverse spacer adapter (TSA) maintains thermal and safety partitions within the adapter cavity. Therefore, the transverse spacer adapter (TSA) addresses the lack of a universal mating interface by adapting to diverse rack and rear-door heat exchanger patterns, addresses the absence of integrated rack-level liquid and power distribution by housing the rack distribution manifold and the redundant rack power distribution units, improves cooling efficiency by preserving door-to-rack sealing and alignment, mitigates condensation risk by managing dewpoint margin and condensate flow, and enables scalable transitions from air-dominant to liquid-dominant operation without cabinet replacement.

### Reversible Mating Flanges

Generally, the reversible mating flanges can mount on both the rack-facing and rear-door heat exchanger (RDHX)-facing surfaces of the transverse spacer adapter (TSA) and can present symmetric, slotted interfaces that couple the transverse spacer adapter to heterogeneous cabinet and door geometries. More specifically, the reversible mating flanges can include a sheet-metal or extruded profile that provides mirrored bolt patterns and elongated slots, and the reversible mating flanges can slide, telescope, or flip to accommodate 600 mm to 800 mm rack widths and hinge-left and/or hinge-right RDHX orientations. In particular, the reversible mating flanges can register to multiple vendor-specific mounting grids by exposing slot patterns and bolt-hole arrays dimensioned to exemplary pitches (e.g., 18 mm to 25 mm) and slot lengths (e.g., 12 mm to 40 mm), and the reversible mating flanges can retain positional adjustment with tool-less fasteners and/or quarter-turn latches that clamp the transverse spacer adapter against the rack and the RDHX. Additionally, the reversible mating flanges can integrate perimeter gaskets or seals formed from closed-cell elastomers (e.g., EPDM or silicone with 25% to 40% compression) to limit air bypass across the rack-spacer and spacer-door interfaces to an exemplary leakage rate below 2% of nominal LFS volumetric flow. Also, the reversible mating flanges can define telescoping rails or overlapping tongues-and-grooves that provide ±10 mm to ±25 mm of depth compliance, and the reversible mating flanges can include hard stops and alignment bosses that constrain squareness within ±0.5 degrees under an exemplary static load of 150 N to 500 N per corner. Further, the reversible mating flanges can provide corrosion protection via zinc-nickel plating or powder coating (e.g., 60 μm to 100 μm thickness) and can maintain mechanical integrity across thermal excursions (e.g., 5° C. to 55° C. ambient) by using 2.0 mm to 4.0 mm wall thickness and reinforcing beads that raise section modulus without increasing mass. Then, the reversible mating flanges can secure the transverse spacer adapter using captive hardware that limits drop risk during field reversal, and the reversible mating flanges can expose gauge marks that guide installers to standardized offsets for common rack brands to reduce installation time to an exemplary 5 minutes to 15 minutes per rack. Therefore, the reversible mating flanges address the lack of a universal adapter by enabling field-reversible, tolerance-compliant attachment to multi-vendor racks and RDHX units, and the reversible mating flanges reduce uncontrolled or reverse airflow by sealing the primary interfaces to limit bypass while supporting retrofits that scale from air-dominant to liquid-dominant deployments without rack or door modification.

### Adapter Cavity

The adapter cavity can define an internal, enclosed compartment within the transverse spacer adapter (TSA) that can route liquid supply and return hoses, power distribution whips, and control wiring between a rack, a rear-door heat exchanger (RDHX), and associated infrastructure while maintaining organized pathways. The adapter cavity can maintain physical segregation between liquid-carrying conduits and electrical conductors by incorporating drip trays, sloped drainage paths (e.g., with a gradient between 1 and 5 degrees), and rigid physical barriers that can channel leakage toward a condensate management assembly without contacting energized conductors. The adapter cavity can include mounting provisions for quick-disconnect couplings, strain reliefs aligned to cable glands, and brackets that can secure liquid lines and electrical harnesses at defined intervals (e.g., between 150 and 300 mm) to control vibration and bend radius. The adapter cavity can provide adjustable geometry to accommodate variations in rack and RDHX standoff distances (e.g., between 25 and 150 mm) by using movable rails and interchangeable filler panels, and the adapter cavity can provide access via removable service panels that can permit inspection or replacement without disturbing adjacent terminations. The adapter cavity can configure an internal layout that can minimize bends and pressure drops in liquid lines by enforcing minimum bend radii (e.g., at least 4 to 8 times hose diameter) and by reserving wide-radius sweep paths that can limit incremental pressure drop to an exemplary range (e.g., less than 5 to 15 kPa across the cavity). The adapter cavity can maintain clear separation distances between wet zones and live zones according to IEC/UL requirements by reserving creepage and clearance spacing (e.g., at least 25 to 50 mm) and by orienting barriers to prevent drip trajectories toward electrical terminations. The adapter cavity can house sensors for leak detection, temperature, and humidity that can report to a controls and sensor suite, and the adapter cavity can trigger annunciation or isolation procedures when a sensor can detect a threshold event (e.g., moisture above 1 ml accumulated or relative humidity above 80% for longer than 30 s). The adapter cavity can include EMI shielding or bonding points that can establish electrical continuity across service panels and barriers and that can reduce electromagnetic interference coupling between power conductors and sensor wiring. The adapter cavity can therefore address mechanical universality by accommodating multi-vendor RDHX and rack geometries, can support integrated liquid and power routing without cross-contamination, and can mitigate condensation-related hazards through drainage and sensing, thereby assisting scalability from air-dominant to liquid-dominant operation without extensive cabinet modification.

### Rack Distribution Manifold (RDM)

The rack distribution manifold (RDM) can mount as a vertically oriented manifold assembly within the transverse spacer adapter (TSA) and can distribute and collect facility-supplied coolant for server cold-plate loops without occupying rack U-space. The rack distribution manifold (RDM) can include a pair of parallel supply and return headers fabricated from corrosion-resistant materials, such as stainless steel and/or polymer, and can size the headers to fit within an adapter cavity of the transverse spacer adapter (TSA). The rack distribution manifold (RDM) can provide multiple lateral branch connections terminated with dry-break quick-disconnect couplings to enable rapid, tool-less connection and disconnection of server liquid lines during maintenance or server replacement. The rack distribution manifold (RDM) can equip each branch with integrated quarter-turn and/or ball-type isolation valves to allow selective servicing of server loops while the rack distribution manifold (RDM) maintains uninterrupted coolant flow to other branches. The rack distribution manifold (RDM) can position duplex strainers or filters upstream of the branch connections to capture particulates and to prevent fouling of cold plates. The rack distribution manifold (RDM) can integrate flow and differential pressure (ΔP) instrumentation, such as inline flow meters and pressure transducers, at strategic points on the supply and return headers to enable real-time monitoring and balancing of coolant flow to each server branch. The rack distribution manifold (RDM) can expose serviceable elements, including filters, valves, and instrumentation, to the cold aisle via removable service panels of the transverse spacer adapter (TSA) to facilitate maintenance during live operation. The rack distribution manifold (RDM) can interface with a coolant distribution unit (CDU) via flexible hose assemblies routed through the transverse spacer adapter (TSA) and can incorporate sloped drip trays and leak detection sensors to manage and monitor potential liquid ingress. The rack distribution manifold (RDM) can support a range of flow rates and temperature differentials to achieve per-rack liquid heat removal capacities up to approximately 160 kW, subject to cold-plate specifications and facility supply conditions. The rack distribution manifold (RDM) can employ a modular design to adapt to various rack heights and server densities, and the rack distribution manifold (RDM) can enable rapid retrofit into existing data center environments without modification to a rack and/or a rear-door heat exchanger (RDHX). Therefore, the rack distribution manifold (RDM) addresses the absence of integrated rack-level liquid distribution within a single spacer assembly, enables dynamic coordination via embedded flow/ΔP telemetry for the hybrid air-liquid control method, mitigates condensation and leak risks via drip management and sensing, and facilitates scalable migration from air-dominant to liquid-dominant cooling without cabinet replacement.

### Isolation Valves

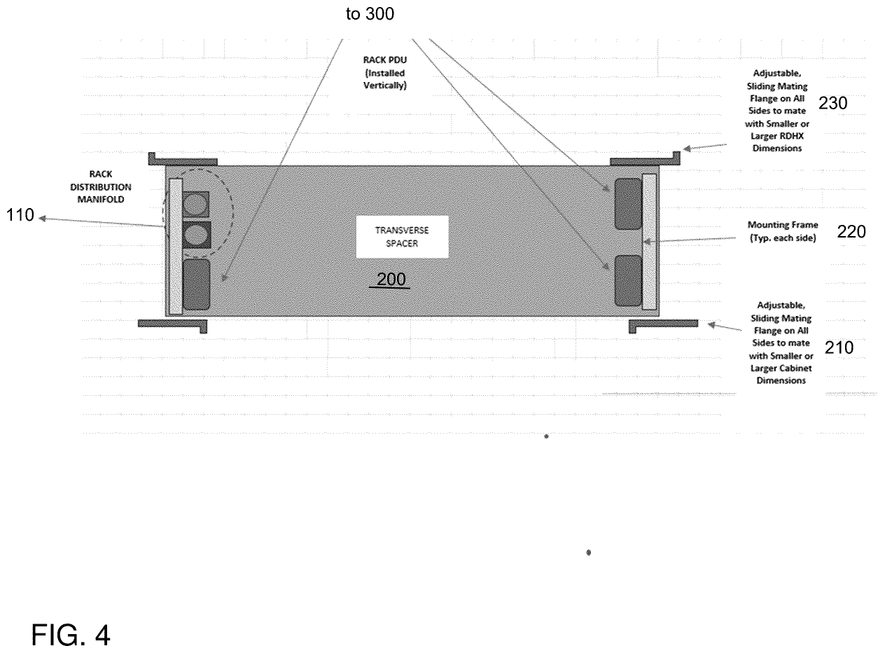

As shown in FIG. 4, the rack distribution manifold (RDM) can integrate isolation valves to segment liquid supply and return paths to a rear-door heat exchanger (RDHX) and/or server cold plate branches, and the isolation valves can position at header takeoffs to enable localized shutdown while the remainder of the rack continues to circulate coolant. In one implementation, the isolation valves can implement quarter-turn ball mechanisms with manual handles or remote actuators to interrupt flow to individual rack segments, and the isolation valves can maintain leak-tight sealing across exemplary secondary loop conditions (e.g., 2-6 bar and 10-40° C.). In another implementation, the isolation valves can include mechanical position indicators, lockout/tagout features, and optional integration with quick-disconnect couplings to accelerate service and minimize fluid loss. More specifically, the isolation valves can cooperate with the RDM inlet and outlet headers to define per-branch isolation points, the isolation valves can throttle or shut off flow to an RDHX during maintenance or fault isolation, and the isolation valves can allow replacement of a liquid-cooled component without draining a pod-level circuit. Therefore, the isolation valves can address field serviceability and uptime challenges by enabling targeted isolation during faults and maintenance, which supports modular adaptation across heterogeneous racks while avoiding full-loop depressurization and associated downtime.

### Flow/δP Instrumentation

Flow/ΔP instrumentation can integrate one or more inline turbine flow meters, ultrasonic flow sensors, and differential-pressure transducers within the rack distribution manifold (RDM) and associated coolant lines to collect water-side measurements in real time. More specifically, flow/ΔP instrumentation can place differential-pressure transducers across inlet and outlet headers and across isolation valves to measure pressure differentials that indicate segment resistance and valve position effects. In particular, flow/ΔP instrumentation can measure volumetric coolant flow rates across RDHX supply and return branches and can report aggregate and per-branch values to the controller. Additionally, flow/ΔP instrumentation can transmit flow and differential-pressure data to the controller to populate a sensor telemetry dataset that the controller can use to calculate control targets and coordinate cooling resources. Also, flow/ΔP instrumentation can maintain measurement accuracy within an exemplary ±2% of full scale for flow and within an exemplary ±1 Pa for differential pressure while operating with technical fluids and temperature ranges (e.g., 5-45° C.) specified for the hybrid-cooled data center rack system. In one implementation, flow/ΔP instrumentation can provide quick-disconnect electrical interfaces and serviceable transducer tees that allow aisle-side replacement and calibration without draining the RDM. In another implementation, flow/ΔP instrumentation can include leak-detection thresholds and alarm relays that the controls and sensor suite can utilize to generate a fault-detection event and to initiate revert to passive state and isolate fault sequences. The rack distribution manifold can route sensor tap lines and can locate transducers downstream of dry-break couplings so that service panels can access instrumentation without disturbing upstream facility connections. The controller can use flow/ΔP instrumentation data to adjust RDHX water flow and for the coolant distribution unit (CDU) to adjust liquid flow and temperature so that the system can prevent pump cavitation, avoid insufficient flow through server cold plates, and balance branch flows. The controller can further use flow/ΔP instrumentation data to determine a liquid cooling fraction setpoint that the hybrid air-liquid rack cooling control method can apply to maintain a desired air-to-liquid heat removal ratio. A facility management system can receive flow/ΔP instrumentation telemetry via the controls and sensor suite for remote monitoring and maintenance diagnostics, and can archive water-side sensor dataset records for trend analysis. Thus, flow/ΔP instrumentation and the rack distribution manifold can address the absence of integrated rack-level liquid distribution feedback, can enable dynamic coordination of air-side and liquid-side heat removal under varying loads, and can support scalable operation from air-dominant to liquid-dominant modes while maintaining condensation safety and cooling efficiency.

### Redundant Rack Power Distribution Units (RPDUs)

As shown in FIG. 4, the redundant rack power distribution units (rpdus) can mount to opposed vertical rails of the transverse spacer adapter (TSA) as dual, independently powered intelligent power distribution assemblies that provide A-side and/or B-side branch-circuit feeds to rack-mounted information technology equipment while preserving rack U-space and shortening power cord runs. The redundant rack power distribution units (rpdus) can present mixed outlet groups (e.g., IEC C13 and/or C19) with per-outlet or per-group current metering, branch-circuit monitoring, and status indication, and the redundant rack power distribution units (rpdus) can expose remote interfaces such as SNMP and/or Modbus to enable out-of-band power telemetry and control. The redundant rack power distribution units (rpdus) can locate serviceable faces toward the front aisle and can separate energized parts from liquid conduits inside the transverse spacer adapter (TSA) by drip trays and physical barriers that maintain creepage, clearance, and ingress protection ratings across a range of environmental conditions (e.g., 10-40 C. and 20-80% RH, each exemplary). The redundant rack power distribution units (rpdus) can include hot-swappable measurement and/or network modules to reduce mean time to repair, and the redundant rack power distribution units (rpdus) can support field-reversible orientation to align with a rear-door heat exchanger (RDHX) hinge side during retrofit. The bonding/grounding stud can provide a designated bonding point that connects the redundant rack power distribution units (rpdus) to a rack safety ground and to EMI gasketing and bonding points to satisfy continuity requirements. The cable glands can route incoming A-side and/or B-side feeders with strain relief and ingress protection to protect conductors against vibration and to maintain segregation from adjacent liquid-handling volumes inside the transverse spacer adapter (TSA). Therefore, the redundant rack power distribution units (rpdus) can integrate redundant power distribution into the transverse spacer adapter (TSA) to eliminate separate power hardware, to enable rapid retrofit without cabinet modification, and to address the absence of integrated rack-level liquid distribution manifolds and redundant power distribution units within a single spacer assembly.

### Controls and Sensor Suite

The controls and sensor suite can include a distributed set of electronic modules and sensors configured to monitor and regulate thermal management of the modular hybrid-cooled data center rack adapter system. The controls and sensor suite can measure rack differential pressure, airflow rates through the longitudinal flow spacer and associated passages, coolant supply and return temperatures, and a rack ambient dewpoint reading using a dewpoint sensor positioned in representative return air and/or at a rack inlet. The controls and sensor suite can interface with a positive return-flow fan (PRFF) array, a rear-door heat exchanger (RDHX) water flow control valve, and a coolant distribution unit (CDU) pump speed controller to issue an actuator command set that coordinates hybrid air and liquid resources. The controls and sensor suite can execute a hybrid air-liquid rack cooling control method to maintain a commanded heat-split by determining a liquid cooling fraction setpoint and by generating cooling control targets for airflow and secondary-loop water conditions. The controls and sensor suite can maintain a positive differential pressure across the rack by modulating longitudinal flow spacer fan speed according to readings from differential-pressure sensors to direct airflow from exhaust to intake. The controls and sensor suite can enforce a minimum dewpoint margin by comparing RDHX supply temperature to a dewpoint margin metric and by reducing RDHX duty or increasing water temperature when condensation risk rises. The controls and sensor suite can aggregate an air-side sensor dataset and a water-side sensor dataset into a sensor telemetry dataset for real-time control and for supervisory integration with building management systems and/or data center infrastructure management platforms. The controls and sensor suite can detect and respond to fault conditions by generating a fault-detection event from flow/Δp instrumentation and by commanding a revert to a passive-isolated cooling configuration that closes gravity backflow dampers, reduces RDHX duty, and increases a liquid cooling fraction setpoint when required to maintain safe heat removal. The controls and sensor suite can implement a distributed network of microcontrollers and/or a centralized controller to support scalable deployment across multiple cabinets and to support pod-level optimization. Thus, the controls and sensor suite can address the inability to dynamically coordinate air-side and liquid-side heat removal, the uncontrolled or reverse airflow between adjacent racks, the risk of condensation on RDHX coils, and the difficulty scaling from air-dominant to liquid-dominant cooling without replacing existing cabinets.

### Controller

The controller receives rack exhaust and intake temperatures, differential-pressure measurements across the rack, rear-door heat exchanger water inlet and outlet temperatures, water and/or coolant flow rates, condensate indications, and room dewpoint values, and the controller processes the inputs to coordinate a longitudinal flow spacer fan array, a rear-door heat exchanger water control, and a rack distribution manifold liquid flow. In one implementation, the controller apportions a fraction of total rack heat removal between an air path and a liquid path by computing a commanded air-to-liquid heat removal ratio and by issuing a liquid cooling fraction setpoint to define f_liquid. Generally, the controller modulates longitudinal flow spacer fan speed to maintain a positive differential pressure between rack exhaust and rack intake within an exemplary range of +5 to +20 pascals and the controller thereby directs airflow and prevents hot-aisle dilution. More specifically, the controller enforces a dewpoint margin by maintaining secondary-loop water supply temperature above measured or calculated room dewpoint by an exemplary increment (e.g., ≥+2° C.) and the controller reduces rear-door heat exchanger duty and/or increases the liquid cooling fraction when the controller detects a compromised margin. Additionally, the controller executes fault-handling routines that detect fan or power failure, that revert operation to passive damper behavior, that selectively close gravity backflow dampers to prevent reverse flow, and that publish alarms to a building management system or a data center infrastructure management platform via protocols such as Modbus, BACnet, and/or SNMP. In one embodiment, the controller stores and executes instructions from a non-transitory computer-readable medium, the controller enables firmware updates and algorithm enhancements, and the controller operates in a centralized and/or distributed architecture with hot-swappable or redundant hardware to improve reliability. Consequently, the controller dynamically coordinates the air-to-liquid heat removal ratio under varying loads, the controller maintains condensation safety via dewpoint margin control, and the controller sustains directed airflow via differential-pressure regulation, thereby addressing uncontrolled or reverse airflow, inability to maintain a target heat removal split, and difficulty scaling between air-dominant and liquid-dominant cooling without cabinet replacement.

### Coolant Distribution Unit (CDU)

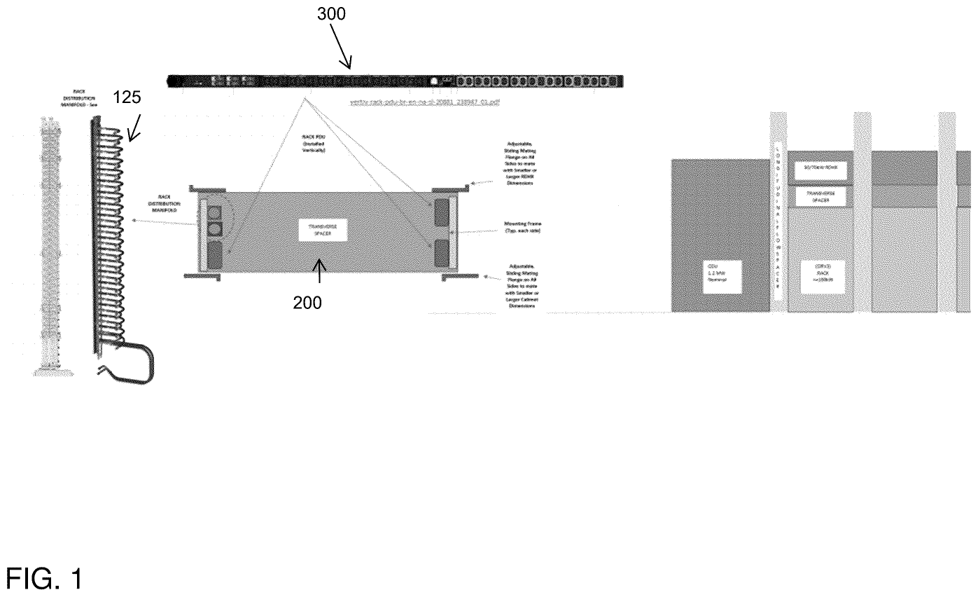

As shown in FIG. 1, the coolant distribution unit (CDU) can supply, circulate, and condition technical fluid for a modular hybrid-cooled data center rack adapter system by executing adjust liquid flow and temperature to produce conditioned secondary-loop coolant. More specifically, the coolant distribution unit (CDU) can include a pump assembly, a heat exchanger, supply and return headers, and control valves with instrumentation to deliver controlled-temperature coolant to a rack distribution manifold (RDM) within a transverse spacer adapter (TSA) and to a secondary loop serving a rear-door heat exchanger (RDHX). In particular, the coolant distribution unit (CDU) can employ variable-speed pumps, modulating valves, and temperature and/or flow sensors to adjust coolant flow rate and supply temperature in response to a sensor telemetry dataset and a cooling control targets input from a controller. Additionally, the coolant distribution unit (CDU) can operate under supervisory coordination with the controller to maintain a commanded liquid cooling fraction setpoint that defines a ratio of air-side to liquid-side heat removal, to enforce a minimum supply temperature margin above a rack ambient dewpoint reading to avoid RDHX condensation, and to balance flow across multiple racks or pods according to a dewpoint margin metric. In one implementation, the coolant distribution unit (CDU) can support hot-swappable pump modules, redundant rack power distribution units (RPDUs) or redundant power supplies, and networked control interfaces for integration with building management systems (BMS) and/or data center infrastructure management (DCIM) platforms. Alternatively, the coolant distribution unit (CDU) can be rated for exemplary rack heat removal capacities up to about 160 kW per rack with scalable configurations for pod-level or row-level deployments. In various installations, the coolant distribution unit (CDU) can be implemented as a floor-standing, sidecar, or overhead-mounted unit and can utilize quick-disconnect dry-break couplings and isolation valves to facilitate installation, maintenance, and retrofit into existing environments. Thus, the coolant distribution unit (CDU) can address dynamic coordination of liquid resources, can maintain condensation safety through dewpoint margin management, and can enable capacity scaling from air-dominant to liquid-dominant cooling without cabinet replacement, thereby resolving load variability and retrofit challenges unique to hybrid-cooled racks.

### Hybrid Air-liquid Rack Cooling Control Method

Generally, a controller can execute the hybrid air-liquid rack cooling control method to coordinate a modular hybrid-cooled data center rack adapter system according to real-time conditions and to generate an actuator command set that produces a stable hybrid-cooled rack operating state. In one embodiment, the controller can acquire a sensor telemetry dataset that aggregates an air-side sensor dataset and a water-side sensor dataset, and the controller can calculate cooling control targets that include a liquid cooling fraction setpoint for a desired air-to-liquid heat removal ratio, a differential-pressure setpoint across a longitudinal flow spacer, and a secondary-loop supply temperature target that maintains a positive dewpoint margin. More specifically, the controller can modulate the positive return-flow fan array to maintain a positive differential pressure, the rear-door heat exchanger can adjust RDHX water flow according to the cooling control targets, and a coolant distribution unit can adjust liquid flow and temperature while a rack distribution manifold can regulate valves to balance server cold-plate flow. In particular, the controller can maintain condensation safety by comparing an RDHX supply temperature to a dewpoint margin metric and, if a dewpoint margin assessment indicates risk, the rear-door heat exchanger can reduce RDHX duty or increase water temperature while the controller can increase a commanded liquid fraction and/or request higher server-fan airflow to raise coil approach temperature. Additionally, the controller can handle faults and state transitions by detecting flow or fan failure via the controls and sensor suite, by reverting to a passive-isolated cooling configuration that closes gravity backflow dampers and idles fans, and by recording a fault event log to support service intervention; in normal operation, the controller can progress through passive, assisted return, hybrid ratio control, and dewpoint margin logic states. Then, the controller can optionally coordinate pod-level operation with a facility BMS or DCIM so that multiple racks share liquid cooling fraction setpoints according to coolant distribution unit capacity and dewpoint margin conditions, thereby enabling scalable migration from air-dominant to liquid-dominant cooling without cabinet replacement. Thus, the controller and the cooperating subsystems can maintain directed airflow to prevent reverse flow between adjacent racks, can dynamically apportion heat removal between air and liquid paths, and can manage dewpoint margin to avoid coil condensation, which collectively address uncontrolled airflow, ratio coordination under varying loads, condensation risk, and scalability challenges in hybrid-cooled racks.

### Calculate Control Targets

Generally, the controller can calculate control targets by ingesting a sensor telemetry dataset that the controls and sensor suite can stream from rack exhaust and intake temperatures, differential-pressure sensors across the rack, rear-door heat exchanger (RDHX) water supply and return temperatures, flow/Δp instrumentation values of the rack distribution manifold (RDM), and a rack ambient dewpoint reading derived from a dewpoint sensor and/or computed psychrometrics. More specifically, the controller can determine an instantaneous thermal load of information-technology equipment and can bound a safe operating envelope for air-side and liquid-side paths based on mechanical and hydraulic constraints of the RDHX, the RDM, and the coolant distribution unit (CDU). In particular, the controller can compute cooling control targets that specify a target split of rack heat removal between an air path via the RDHX and a liquid loop via the RDM such that the aggregate capacity meets or exceeds the computed load. Additionally, the controller can enforce a condensation constraint by maintaining a secondary-loop supply temperature according to and can record a dewpoint margin metric for supervisory logic. In one implementation, the controller can execute compute dewpoint margin to fuse the rack ambient dewpoint reading with secondary-loop temperatures and to update the dewpoint margin metric at periodic intervals and/or threshold events. In another implementation, the controller can execute determine desired air-to-liquid heat removal ratio to generate a liquid cooling fraction setpoint that the controller can include within the cooling control targets for downstream actuators. Also, the controller can validate that commanded air and liquid flows implied by the cooling control targets do not exceed pressure and flow limits of the RDHX, the RDM, and the CDU, and the controller can rescale targets when constraints arise. Alternatively, the controller can use a closed-loop algorithm that iteratively adjusts the air/liquid split in response to changes in IT load, environmental conditions, or system alarms, and the controller can bias the split to maintain a differential-pressure setpoint that the longitudinal flow spacer (LFS) and the positive return-flow fan (PRFF) array can satisfy. In one embodiment, the controller can minimize energy consumption by referencing rule-based logic and/or lookup tables and can optionally apply a model-predictive control (MPC) variant to forecast near-term loads and to preempt constraint violations. Then, the controller can publish the cooling control targets as inputs to coordinate cooling resources, thereby enabling subsequent modulation of liquid flow and temperature, RDHX water flow, and LFS fan speed while preserving the dewpoint margin. Thus, the controller addresses the inability to dynamically coordinate an air-to-liquid ratio across varying loads while maintaining condensation safety and enabling scalable transitions between air-dominant and liquid-dominant operation without exceeding component capacities.

### Monitor System Parameters

The controls and sensor suite can execute the monitor system parameters step by polling or streaming sensor values at an interval (e.g., between 1 and 10 seconds). The controller can acquire real-time operational data that includes rack exhaust air temperature, rack intake air temperature, differential air pressure measured between the rack exhaust and intake, server inlet relative humidity, secondary-loop water supply temperature, secondary-loop water return temperature, and flow rates of air and liquid cooling circuits. The differential-pressure sensors can measure an air-side pressure differential to characterize cross-rack airflow containment and to support subsequent fan control. The flow/Δp instrumentation can measure secondary-loop flow and hydraulic differential to characterize RDHX heat transfer capacity and coolant availability. The dewpoint sensor can generate a rack ambient dewpoint reading and can supplement or substitute server inlet relative humidity sensing where configuration warrants. The controller can time-stamp each acquired value, can aggregate the values into a sensor telemetry dataset, and can buffer the sensor telemetry dataset for real-time control, historical logging, and fault detection. The controller can process the sensor telemetry dataset to establish an instantaneous thermal state of the rack, can detect deviations from cooling control targets, and can prepare inputs for modulate LFS fan speed to maintain differential pressure, adjust liquid flow and temperature, and adjust RDHX water flow. The controller can adapt a monitoring cadence and a sensor selection based on control loop stability, workload dynamics, or facility management system integration constraints. The controls and sensor suite can interface with direct-wired sensors and/or networked sensor arrays and can support local acquisition within the rack and remote acquisition via a facility network. The controller can publish the sensor telemetry dataset for calculate control targets, coordinate cooling resources, maintain condensation safety, and handle faults and state transitions so that downstream steps receive coherent, time-aligned inputs. Therefore, the controls and sensor suite address uncontrolled or reverse airflow via differential-pressure monitoring, the controller supports dynamic coordination of air-side and liquid-side heat removal via comprehensive telemetry, and the dewpoint sensor mitigates condensation risk by enabling timely assessment of dewpoint margin, which collectively support scalable operation from air-dominant to liquid-dominant modes.

### Coordinate Cooling Resources

As part of the hybrid air-liquid rack cooling control method, the controller can coordinate cooling resources by consuming the cooling control targets and the sensor telemetry dataset and by issuing an actuator command set that sequences valve positions, pump speeds, and fan speeds according to a desired air-to-liquid heat removal ratio, a differential-pressure setpoint, and a dewpoint margin. More specifically, the controller can adjust liquid flow and temperature by commanding the coolant distribution unit (CDU) to ramp secondary-loop pump speed and to trim a mixing or bypass valve so that conditioned secondary-loop coolant follows a temperature trajectory that maintains a margin above a rack ambient dewpoint reading (e.g., ≥2 to 5° C.) while tracking a liquid cooling fraction setpoint. In addition, the controller can adjust RDHX water flow by directing the rear-door heat exchanger (RDHX) to increase or decrease a control valve position and to stage coil circuits so that RDHX duty aligns with the desired air-to-liquid heat removal ratio without crossing a dewpoint margin metric. Furthermore, the controller can modulate LFS fan speed to maintain differential pressure by commanding the positive return-flow fan (PRFF) array to ramp fan trays to hold a rack exhaust-to-intake pressure of, for example, +5 to +20 Pa, while the longitudinal flow spacer (LFS) coordinates gravity backflow dampers to prevent reverse flow during transients. In one embodiment, the controller can implement a state machine that first increases secondary-loop water supply temperature or reduces RDHX water flow before decreasing PRFF speed, and the controller can verify each transition with temperature, humidity, differential-pressure, flow/Δp instrumentation, and condensate management assembly feedback to avoid overshoot and to honor operational constraints. In another embodiment, the controller can execute a closed-loop or model-predictive control algorithm that continuously updates the actuator command set in response to detected IT load changes, environmental disturbances, or fault-detection event, and a supervisory controller can coordinate multiple racks or pods to share capacity while preserving rack-level constraints. Therefore, the controller coordinates cooling resources to maintain the target air-to-liquid heat removal ratio under varying loads, to prevent condensation on RDHX coils by preserving dewpoint margin, and to inhibit reverse airflow between adjacent racks by sustaining positive differential pressure, which collectively addresses cooling inefficiency and enables scalable transitions between air-dominant and liquid-dominant operation.

### Adjust Liquid Flow and Temperature

Generally, a coolant distribution unit (CDU) can adjust liquid flow and temperature by modulating a pump speed and, where available, actuating a mixing and/or bypass valve to achieve a target mass flow rate and a target supply temperature that correspond to a commanded liquid cooling fraction. More specifically, a controller can issue a cooling control target and a liquid cooling fraction setpoint, and the coolant distribution unit (CDU) can increase or decrease pump rotational speed to raise or lower volumetric flow while the coolant distribution unit (CDU) positions a mixing and/or bypass valve to blend return water with supply water or to divert a portion of flow for supply temperature trimming. In particular, the coolant distribution unit (CDU) can deliver conditioned secondary-loop coolant to a rack distribution manifold (RDM) and/or a rear-door heat exchanger (RDHX) at a supply temperature and a mass flow rate sized to remove a specified portion of rack thermal load, where the controls and sensor suite can stream a sensor telemetry dataset including inlet and outlet air temperatures, loop flow rates, and estimated heat load. Additionally, the controller can enforce a condensation constraint by comparing a supply temperature to a dewpoint sensor reading plus a safety margin and by commanding the coolant distribution unit (CDU) to honor (e.g., with an exemplary margin between 1 K and 5 K) to prevent coil condensation. Then, the coolant distribution unit (CDU) can execute closed-loop regulation using continuous feedback from temperature, flow/Δp instrumentation, and dewpoint sensor, or alternatively, the coolant distribution unit (CDU) can follow open-loop schedules aligned to forecast load profiles, with periodic updates at intervals (e.g., between 1 s and 30 s) or event-driven updates triggered by changes in rack load and/or dewpoint margin status. Furthermore, the coolant distribution unit (CDU) can generate an actuator command set that specifies pump speed, valve position, and supply temperature targets while the rack distribution manifold (RDM) can distribute the commanded flow to connected branches for stable delivery to the rear-door heat exchanger (RDHX). Thus, the coolant distribution unit (CDU) and the controller coordinate liquid-side capacity to track a desired air-to-liquid heat removal ratio, to avoid condensation under varying ambient humidity, and to enable gradual scaling from air-dominant operation toward liquid-dominant operation without cabinet replacement, which addresses dynamic coordination, condensation risk management, and upgrade flexibility challenges in the field.

### Maintain Condensation Safety

Generally, the controller can maintain condensation safety by receiving the rack ambient dewpoint reading from the dewpoint sensor and by computing a dewpoint margin metric according to compute dewpoint margin, where the controller can define the dewpoint margin metric as a difference between a rear-door heat exchanger (RDHX) supply-water temperature and the rack ambient dewpoint reading; the controller can then compare RDHX supply temperature to dewpoint margin to evaluate a risk condition. More specifically, the controller can interpret the sensor telemetry dataset to detect dewpoint values according to detect dewpoint and to correlate the dewpoint margin metric with the water-side sensor dataset and the air-side sensor dataset to establish a time-varying ΔT_margin threshold (e.g., between 2 and 5 degrees C., as an example range). In particular, the controller can issue the actuator command set to reduce RDHX duty or increase water temperature when the controller determines that the dewpoint margin assessment indicates ΔT_margin below the threshold and/or when the condensate management assembly signals liquid presence. Additionally, the coolant distribution unit (CDU) can adjust liquid flow and temperature to raise the secondary-loop supply temperature and/or to decrease RDHX flow, and the rack distribution manifold (RDM) can increase flow to cold plates to shift a greater fraction of heat removal to the liquid path to reduce the air-side load on the RDHX. Also, the longitudinal flow spacer (LFS) and the positive return-flow fan (PRFF) array can modulate airflow profile to increase an airside approach temperature at the RDHX face while the controller can coordinate cooling resources to preserve differential pressure targets. Thus, the controller and the cooperating fluid and airflow components can prevent coil condensation under variable load and ambient humidity conditions, which addresses the risk of condensation on RDHX coils due to insufficient dewpoint margin management in secondary water loops.

### Compare RDHX Supply Temperature to Dewpoint Margin

Generally, the controller can execute compare RDHX supply temperature to dewpoint margin by ingesting the sensor telemetry dataset from the controls and sensor suite and by evaluating the rear-door heat exchanger (RDHX) secondary-loop supply temperature against a threshold derived from a rack ambient dewpoint reading and a configurable safety offset. More specifically, the controller can compute a violation criterion according to the following relation: In one implementation, the controller can configure ΔT_margin_set within an exemplary range (e.g., 1-4° C.) with a nominal value (e.g., 2° C.) and can evaluate the criterion at a cadence (e.g., 1-10 Hz) with a persistence filter and a hysteresis band to avoid actuator chatter. In particular, the controller can generate a dewpoint margin assessment as an output that classifies each evaluation as compliant or violating and can log a scalar margin value (e.g., T_supply, secondary—T_dewpoint—ΔT_margin_set) for downstream decision logic. Additionally, the controller can adapt ΔT_margin_set based on environmental or operational parameters by referencing the air-side sensor dataset, the water-side sensor dataset, and the flow/Δp instrumentation, and the controller can increase the margin during high-humidity trends or during low-airflow indications from the longitudinal flow spacer (LFS). Alternatively or additionally, the model-predictive control (MPC) variant can forecast the dewpoint margin using predicted server load, conditioned secondary-loop coolant temperatures, and RDHX flow states to preempt a future violation. Then, upon detecting a condition where T_supply, secondary falls below the threshold, the controller can flag a dewpoint margin violation and can synthesize an actuator command set that requests protective actions for execution by the rear-door heat exchanger and/or the coolant distribution unit, while handing detailed actuation to a subsequent reduce RDHX duty or increase water temperature step. Thus, the controller maintains condensation safety by continuously proving that the RDHX coil approach temperature remains above a configurable dewpoint margin, which addresses the field challenge of condensation risk on RDHX coils under varying environmental and load conditions.

### Reduce RDHX Duty or Increase Water Temperature

Generally, the rear-door heat exchanger (RDHX) can execute the reduce RDHX duty or increase water temperature step by processing a dewpoint margin assessment and a sensor telemetry dataset to maintain a coil surface temperature at least a target margin (e.g., 2-5° C.) above a rack ambient dewpoint reading. More specifically, the rear-door heat exchanger (RDHX) can generate an actuator command set that throttles coolant flow through an internal or manifolded control valve to reduce thermal duty by an exemplary 5-50% in increments of 1-5% while limiting a rate-of-change to an exemplary 2-10% per minute to avoid oscillation. In one implementation, the coolant distribution unit (CDU) can raise a secondary-loop supply temperature setpoint by an exemplary 0.2-1.0° C. per minute until the dewpoint margin metric exceeds a configured threshold, and the coolant distribution unit (CDU) can cap the setpoint within an exemplary range of 18-30° C. to preserve upstream chiller efficiency. Additionally, the positive return-flow fan (PRFF) array can temporarily increase fan speed by an exemplary 5-20% to raise an air-side approach temperature across the rear-door heat exchanger (RDHX) when the coolant adjustments alone do not restore the dewpoint margin. In another implementation, the controller can select a combined action by prioritizing the least disruptive actuator based on the sensor telemetry dataset, and the controller can revert adjustments once the dewpoint margin metric sustains above a hysteresis band for an exemplary 60-180 seconds. In one variant, the model-predictive control (MPC) variant can forecast dewpoint excursions over an exemplary 2-10 minute horizon and can pre-emptively schedule smaller flow reductions and setpoint increases to minimize transient temperature swings at server inlets. Then, the rear-door heat exchanger (RDHX) can confirm condensation-free operation by correlating coil surface temperature estimates with condensate management assembly inputs and can clamp duty if any condensate indication persists. Therefore, the rear-door heat exchanger (RDHX), the coolant distribution unit (CDU), the positive return-flow fan (PRFF) array, and the controller can coordinate flow throttling, water temperature elevation, and airflow modulation to eliminate coil-surface undershoot below dewpoint, thereby addressing the risk of condensation on rear-door heat exchanger (RDHX) coils under varying thermal loads and humidity conditions.

### Handle Faults and State Transitions

Generally, the controller can handle faults and state transitions by evaluating a sensor telemetry dataset and by issuing an actuator command set that configures a degraded operating state when the controller identifies unsafe operation of a longitudinal flow spacer (LFS), a positive return-flow fan (PRFF) array, gravity backflow dampers, a rear-door heat exchanger (RDHX), and/or a coolant distribution unit (CDU). More specifically, the controls and sensor suite can detect flow or fan failure by comparing fan tachometer feedback of the PRFF array and differential readings of flow/Δp instrumentation to expected ranges and by classifying a fault-detection event when the controls and sensor suite observes loss of PRFF power, stalled tachometer counts, or out-of-range temperature, pressure, and condensate signals. In particular, the controller can revert to passive state and isolate fault by commanding a passive-isolated cooling configuration that closes or selectively opens gravity backflow dampers to prevent reverse airflow, reduces RDHX duty and/or increases secondary-loop water temperature to restore a dewpoint margin metric, and segments liquid paths via isolation valves of a rack distribution manifold (RDM) to bypass affected components. Additionally, the controller can transmit alarm signals and a fault event log to facility systems by reporting the nature and location of the fault and by exposing a manual or remote override that service personnel can use through the controls and sensor suite to hold or step the degraded operating state. Then, the controller can maintain condensation safety during the degraded operating state by adjusting liquid flow and temperature at the CDU, by adjusting RDHX water flow at the RDHX, and by modulating LFS-related setpoints that maintain airflow directionality until the controller verifies fault clearance and restores a stable hybrid-cooled rack operating state. Alternatively, the controller can redistribute cooling loads among adjacent racks or pods by modifying the actuator command set to shift the liquid cooling fraction setpoint and by prioritizing airflow via the PRFF array where capacity remains available. Thus, the controller addresses uncontrolled or reverse airflow and condensation risk under fault conditions by preserving airflow directionality, maintaining dewpoint safety margins, and sustaining hybrid cooling continuity without requiring cabinet replacement or extensive modification.

### Revert to Passive State and Isolate Fault

Generally, the controller can execute revert to passive state and isolate fault in response to a fault-detection event by commanding a passive-isolated cooling configuration that deactivates a subset of the positive return-flow fan (PRFF) array and that seats the gravity backflow dampers to prevent reverse airflow between adjacent racks. More specifically, the controller can disable affected fan trays of the PRFF array and can maintain remaining fan trays at a reduced speed only if the differential-pressure sensors indicate that a target containment pressure remains achievable without crossflow. In one implementation, the controller can reassess available cooling resources by ingesting a sensor telemetry dataset that includes flow/Δp instrumentation values at the rack distribution manifold (RDM), air-side readings from the longitudinal flow spacer (LFS), and thermal capacity indicators of the rear-door heat exchanger (RDHX). In particular, the controller can recalculate a liquid cooling fraction setpoint and can generate an actuator command set that adjusts RDHX water flow via the RDHX and that adjusts liquid flow and temperature via the coolant distribution unit (CDU) to achieve a safe air-side and liquid-side heat removal ratio under a degraded operating state. Additionally, the controller can raise a secondary-loop water temperature setpoint when a dewpoint sensor and a computed dewpoint margin metric indicate reduced margin, and the controller can reduce RDHX duty when a dewpoint margin assessment predicts condensation risk. Also, the rack distribution manifold can isolate a failed liquid-side branch by closing isolation valves and, when service is required, the rack distribution manifold can uncouple a branch via dry-break couplings to enable physical removal without draining the entire loop. Further, the redundant rack power distribution units (RPDUs) can electrically isolate a failed PRFF array segment and can signal an operator via a service alarm while the controller logs event details to a fault event log for maintenance tracking. Thus, the controller and the associated subsystems can preserve airflow integrity, can maintain condensation safety, and can sustain cooling capacity with a revised air-to-liquid split during faulted conditions, which addresses reverse airflow, dynamic coordination, and secondary-loop condensation challenges without requiring cabinet replacement.

We claim:

1. A modular hybrid-cooled data center rack adapter system comprising:
a transverse spacer adapter (TSA) positioned between an information-technology equipment rack and a rear-door heat exchanger (RDHX);
reversible mating flanges on the TSA, the flanges having mirrored bolt patterns and elongated slots to mate with racks and RDHX units of differing widths and hinge orientations;
an internal rack distribution manifold (RDM) housed within the TSA, the RDM including supply and return headers equipped with quick-disconnect couplings for server liquid loops;
redundant rack power distribution units (RPDUs) mounted inside the TSA, wherein the RPDUs are physically separated from liquid conduits within the TSA;
a longitudinal flow spacer (LFS) disposed between adjacent racks and defining a guided return-air pathway;
gravity backflow dampers within the LFS that default closed and open under a forward pressure differential;
a variable-speed positive return-flow fan (PRFF) array within the LFS;
a controls and sensor suite including differential-pressure sensors, a dewpoint sensor, and a controller operatively coupled to the PRFF array, the RDM, and the RDHX;
wherein the controller is configured to maintain: (i) a positive differential pressure from rack exhaust to rack intake; and (ii) a minimum temperature margin between a secondary-loop coolant supply temperature and a measured room dewpoint.

2. The modular hybrid-cooled data center rack adapter system of claim 1 wherein the reversible mating flanges further cooperate with a depth shim set to reconcile depth mismatches between the information-technology equipment rack and the rear-door heat exchanger.

3. The modular hybrid-cooled data center rack adapter system of claim 1 wherein the TSA further comprises a condensate management assembly including sloped drip trays and leak sensors configured to signal the controller to initiate mitigation actions.

4. The modular hybrid-cooled data center rack adapter system of claim 1 wherein the PRFF array is implemented as a plurality of hot-swappable fan trays having blind-mate electrical connectors.

5. The modular hybrid-cooled data center rack adapter system of claim 1 wherein the RDM further includes flow/ΔP instrumentation configured to transmit real-time liquid flow rate and differential pressure data to the controller.

6. The modular hybrid-cooled data center rack adapter system of claim 1 wherein the TSA incorporates EMI gasketing and bonding points providing a continuous electromagnetic shield and ground path between the information-technology equipment rack and the rear-door heat exchanger.

7. The modular hybrid-cooled data center rack adapter system of claim 1 wherein the TSA further includes cable glands and abonding/grounding studfor strain-relieved ingress of RPDU power whips and network cables.

8. A hybrid air-liquid rack cooling control method comprising:
monitoring, by a controller, a sensor telemetry dataset that includes rack exhaust and intake temperatures, differential pressure, dewpoint, and liquid flow parameters;
calculating control targets that include a liquid cooling fraction setpoint and a differential-pressure setpoint;
coordinating cooling resources by:
adjusting a liquid flow rate and a supply temperature via a coolant distribution unit (CDU);
adjusting RDHX water flow through a proportional valve;
modulating LFS fan speed to maintain the differential-pressure setpoint;
maintaining condensation safety by comparing an RDHX supply water temperature to a dewpoint and, in response to a margin threshold being violated, reducing RDHX duty or increasing the supply water temperature;
handling faults by detecting a flow or fan failure and reverting a system to a passive-isolated cooling configuration while continuing liquid-side heat removal.

9. The hybrid air-liquid rack cooling control method of claim 8 wherein the monitoring step further comprises collecting air-side measurements from differential-pressure sensors and a dewpoint sensor to augment the sensor telemetry dataset.

10. The hybrid air-liquid rack cooling control method of claim 8 wherein calculating the control targets further comprises computing a dewpoint margin metric ΔT_margin and enforcing the ΔT_margin to be at least 2° C.

11. The hybrid air-liquid rack cooling control method of claim 8 wherein coordinating the cooling resources further comprises generating an actuator command set directed to a positive return-flow fan array, an RDHX valve, and a CDU pump.

12. The hybrid air-liquid rack cooling control method of claim 8 wherein maintaining condensation safety further comprises increasing a server fan speed to raise an air-side approach temperature.

13. The hybrid air-liquid rack cooling control method of claim 8 wherein handling the faults further comprises writing a fault event log and issuing alarms to a facility management system.

14. The hybrid air-liquid rack cooling control method of claim 8 wherein all control logic is executed by the controller contained within the controls and sensor suite.

15. A model-predictive control (MPC) based controller for a hybrid-cooled data-center rack, the controller embodied on a non-transitory computer-readable medium, comprising:
a reduced-order thermo-fluid model configured to predict rack temperature, pressure, and dewpoint trajectories 60-180 seconds ahead;
an optimisation routine configured to minimise projected energy consumption and dewpoint-violation risk while respecting a commanded liquid cooling fraction and a differential-pressure constraint;
an output generator configured to produce optimal trajectories for a CDU pump speed, an RDHX valve position, an LFS fan rotational speed, and server-fan offset values.

16. The controller of claim 15 wherein the optimisation routine is configured to receive a sensor telemetry dataset updated at intervals between 1 and 10 seconds.

17. The controller of claim 15 wherein the output generator is configured to transmit an actuator command set over an industrial communication protocol selected from the group consisting of Modbus, BACnet, and CANbus.

18. The controller of claim 15 wherein a prediction horizon of the reduced-order thermo-fluid model is adaptively lengthened in response to detection of a load transient to improve disturbance rejection.

19. The controller of claim 15 configured to switch to fallback proportional-integral-derivative control in response to generation of a fault-detection event indicating a sensor failure.

20. The controller of claim 15 further configured to coordinate multiple racks by allocating liquid cooling fractions among racks according to available CDU capacity while maintaining individual rack dewpoint margins.
